(19) United States
(12) Patent Application Publication
(10) Pub. No.: US 2017/0172011 A1
(43) Pub. Date: Jun. 15, 2017

(54) COOLING DEVICE

(71) Applicant: HON HAI PRECISION INDUSTRY CO., LTD., New Taipei (TW)

(72) Inventors: CHIN-HUI CHEN, New Taipei (TW); CHIA-YUN LEE, New Taipei (TW); CHENG-HSIU YANG, New Taipei (TW); YUEH-LIN TSAI, New Taipei (TW)

(21) Appl. No.: 14/982,956

(22) Filed: Dec. 29, 2015

(30) Foreign Application Priority Data
Dec. 14, 2015 (CN) 201510920618.4

(51) Int. Cl. H05K 7/20; H05K 1/02

(52) U.S. Cl. CPC H05K 7/20236; H05K 7/20254; H05K 1/0203

(57) ABSTRACT

A cooling device includes a cooling tank, a plurality of circuit board modules received in the cooling tank, and a fill unit received in the cooling tank. The fill unit includes a plurality of first fill modules corresponding to the plurality of circuit board modules. The plurality of first fill modules, the cooling tank and the circuit board modules form a gap, and a plurality of coolant is filled in the gap to dissipate heat for the plurality of circuit board modules.

### FIELD

The subject matter herein generally relates to a cooling device.

### BACKGROUND

In immersion cooling systems, a number of circuit boards are located in a cooling tank, and the cooling tank is filled by an amount of coolant to dissipate heat from the circuit boards.

### BRIEF DESCRIPTION OF THE DRAWINGS

Implementations of the present technology will now be described, by way of example only, with reference to the attached figures.

FIG. 1 is an exploded, isometric view of a first embodiment of a cooling device.

FIG. 2 is an assembled, isometric view of the cooling device of FIG. 1.

FIG. 3 is an assembled, isometric view of a second embodiment of a cooling device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising,” when utilized, means “including, but not necessarily limited to”; it specifically indicates open-ended inclusion or membership in the so-described combination, group, series and the like.

The present disclosure relates to a cooling device.

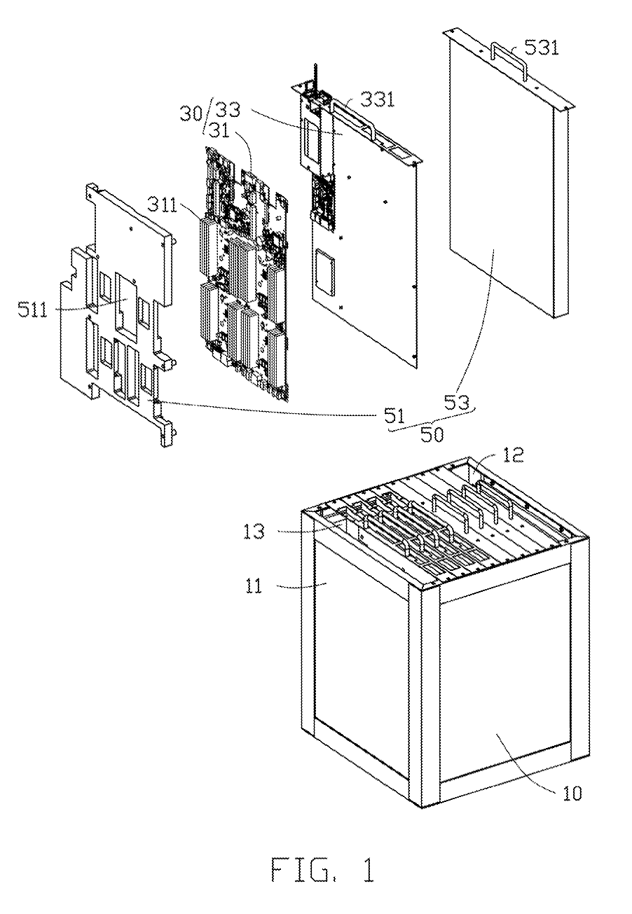

FIG. 1 illustrates a first exemplary embodiment of cooling device. The cooling device comprises a cooling tank 10, a plurality of circuit board modules 30 located in the cooling tank 10, and a fill unit 50 located in the cooling tank 10.

The cooling tank 10 comprises a shell 11 that defines a receiving space 12. The shell having a top portion defines an opening 13.

Each of the circuit board modules 30 comprises a circuit board 31 and a support plate 33. Each circuit board 31 is mounted on the corresponding support plate 33. A handle 331 is mounted on a top portion of each support plate 33. A plurality of electronic components 311 are mounted on each of the circuit boards 31.

The fill unit 50 comprises a plurality of first fill modules 51 and a plurality of second fill modules 53. In at least one embodiment, each of the first fill modules 51 can be a plate, and the plate can occupy a volume of the receiving space 12 of the cooling tank 10. The plate defines a plurality of through holes 511 to receive the electronic components 311 of each circuit board 31. Each of the circuit boards 31 is mounted between the corresponding support plate 33 and the corresponding first fill module 51.

In at least one embodiment, each of the second fill modules 53 can be a plate. The plate can occupy a volume of the receiving space 12 of the cooling tank 10. A handle 531 is mounted on each plate.

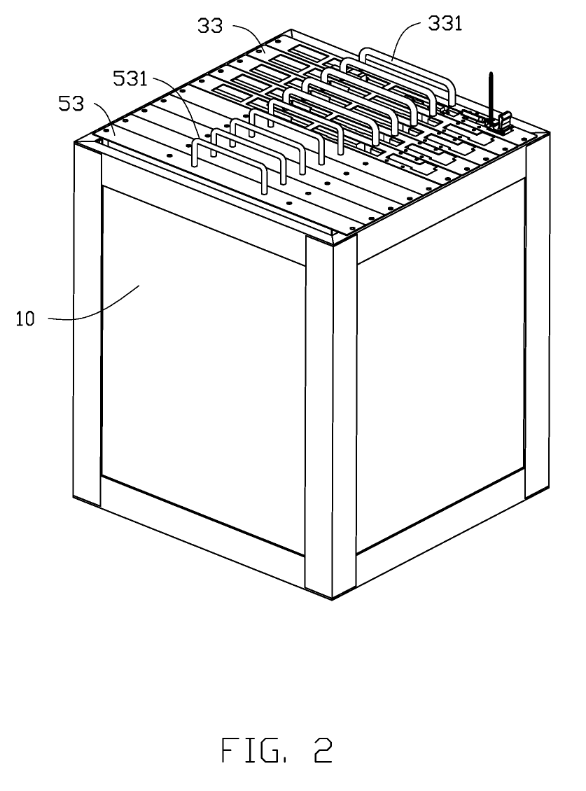

FIG. 2 illustrates an assembled, isometric view of the first exemplary embodiment of the cooling device. In assembly of the cooling device, each first fill module 51 is mounted on one side of the corresponding circuit board 31 of the circuit board module 30, and the electronic components 311 of each circuit board 31 are received in the through holes 511 of the corresponding first fill module 51. A quantity of the circuit board modules 30 can be adjusted based on need. The circuit board modules 30 are inserted into the receiving space 12 of the cooling tank 10 adjoining one side of the cooling tank 10, and the handle 331 of each support plate 33 protrudes out the corresponding opening 13 of the cooling tank 10. The remaining space of the cooling tank 10 is inserted into a plurality of the second fill modules 53 to fill in the receiving space 12 of the cooling tank 10. The handle 531 of each fill module 53 protrudes out of the corresponding opening 13 of the cooling tank 10. A gap is formed between the cooling tank 10 with the first fill modules 51, the second fill modules 53, and the circuit board modules 30. An amount of coolant is infused in the receiving space 12 of the cooling tank 10, and is immerged in the gap and the through holes 511 of the first fill modules 51 to dissipate heat from the electronic components 311 of the circuit boards 31. When the circuit board modules 30 and the fill unit 50 need to be disconnected from the cooling tank 10, the handle 331 of each support plate 33 and the handle 531 of each second fill module 53 are pulled out.

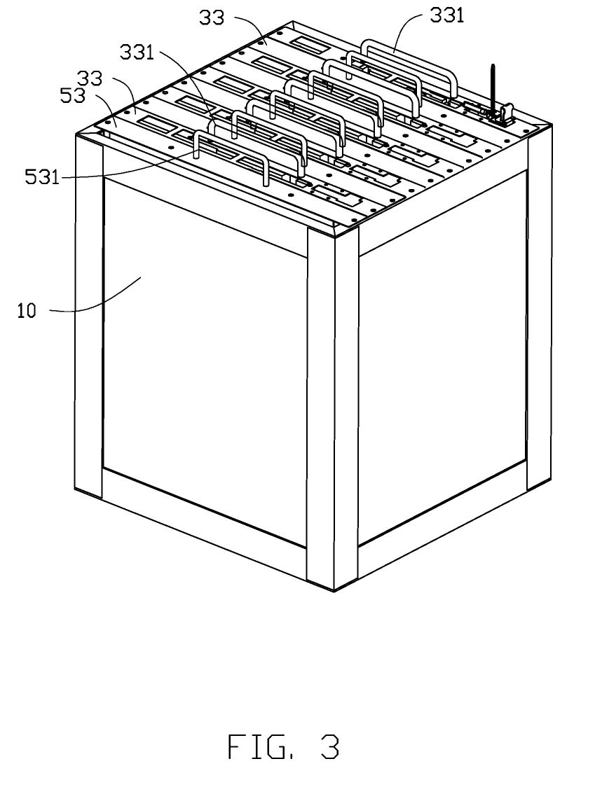

FIG. 3 illustrates an assembled, isometric view of a second exemplary embodiment of the cooling device. A difference between the first exemplary embodiment of the cooling device and the second exemplary embodiment of the cooling device is that the circuit board modules 30 and the second fill modules 53 are spaced from each other in the second exemplary embodiment of the cooling device. Therefore, one circuit board module 30 corresponds with one first fill module 51 and are adjacent to the corresponding second fill modules 53.

The embodiments shown and described above are only examples. Even though numerous characteristics and advantages of the present technology have been set forth in the foregoing description, together with details of the structure and function of the present disclosure, the disclosure is illustrative only, and changes may be made in the details, including matters of shape, size, and arrangement of the parts within the principles of the present disclosure, up to and including the full extent established by the broad general meaning of the terms used in the claims.

1. A cooling device comprising:
a cooling tank;
a plurality of circuit board modules received in the cooling tank; and
a fill unit received in the cooling tank and comprising a plurality of first fill modules corresponding to the plurality of circuit board modules;
wherein the plurality of first fill modules, the cooling tank and the circuit board modules form a gap, which is filled with coolant to dissipate heat from the plurality of circuit board modules; each of the plurality of circuit board modules comprises a circuit board, a plurality of electronic components are mounted on each of the circuit boards, and each of the first fill modules defines a plurality of through holes to receive the electronic components.

2. The cooling device of claim 1, wherein each of the plurality of first fill modules is a plate, and the plate occupies a volume of a space of the cooling tank.

3. The cooling device of claim 1, wherein each of the plurality of circuit board modules further comprises support plate to mount the circuit board, each circuit board is mounted between corresponding support plate and the corresponding first fill module, and a handle is mounted on a top portion of each support plate.

4. (canceled)

5. The cooling device of claim 3, wherein a top portion of the cooling tank defines an opening to receive the handle of each support plate.

6. The cooling device of claim 1, wherein the fill unit further comprises a plurality of second fill modules, and the plurality of second fill modules are abreast located in one side of the plurality of circuit board modules.

7. The cooling device of claim 6, wherein each of the plurality of second fill modules is a plate, and the plate occupies a volume of a space of the cooling tank.

8. The cooling device of claim 6, wherein a handle is mounted on each of the second fill modules.

9. The cooling device of claim 1, wherein the fill unit further comprises a plurality of second fill modules, and the circuit board modules and the second fill modules are spaced from each other.
